(19) United States
(12) Patent Application Publication
(10) Pub. No.: US 2007/0138600 A1
(43) Pub. Date: Jun. 21, 2007

(54) Device for cleaning and drying of wafers

(76) Inventor: Raik Hartlep, Heilbronn (DE)

Correspondence Address: MCGRATH, GEISSLER, OLDS & RICHARDSON, PLLC, P.O. BOX 1364, FAIRFAX, VA, 22038-1364, US

(21) Appl. No.: 11/638,589

(22) Filed: Dec. 14, 2006

(30) Foreign Application Priority Data
Dec. 15, 2005 (DE) DE102005059850.1

(51) Int. Cl. H01L 29/06

(52) U.S. Cl. 257/626

(57) ABSTRACT

A wafer processing device is disclosed that includes a processing chamber, which is surrounded by a housing, an arrangement of inlet openings within the processing chamber, which are provided to dispense a liquid, and a rotatable holding device for wafers. Whereby the wafers are disposed in a wafer carrier, which is fixed to the holding device, in which a coating of a fluoropolymer, preferably PTFE, is provided on all parts of the wafer processing device coming into contact with liquid.

This nonprovisional application claims priority under 35 U.S.C. §119(a) on German Patent Application No. DE 102005059850, which was filed in Germany on Dec. 15, 2005, and which is herein incorporated by reference.

### BACKGROUND OF THE INVENTION

1. Field of the Invention

The present invention relates to a wafer processing device.

2. Description of the Background Art

Integrated circuits, such as microprocessors or memory chips, and other similar assemblies are typically produced on thin round disks or wafers. During their manufacture, these undergo many successive process steps, including cleaning steps, which are typically carried out in rinsing and drying processes.

The manufacturing yield of large-scale integrated circuits depends considerably on the cleanliness of the wafer during the entire process. Contaminants, in this case, can be both particles and chemical contaminations, which are deposited from the process environment on the disk surface. Both contaminants cannot be strictly separated from one another, because chemical components of particles diffuse into silicon especially in high temperature processes and can locally change the electrical or mechanical properties of the material.

Particle contamination occurs by depositions from the ambient air, gases, and liquids. Major sources are wear debris produced by moving parts in machines and flaking-off layers, e.g., in CVD (Chemical Vapor Deposition) processes. Deposition and adherence of particles thereby depend greatly on the specific electrostatic charge state. Particles adhering to the disk surface in photoprocesses result in nonhomogeneous lacquer thicknesses and short circuits or breaks in the lacquer tracks. Etching and implantation processes can be masked locally, so that short circuits and breaks can occur here as well. The incorporation of particles into insulation layers produces sites with a reduced breakdown strength or vertical short circuits.

Metal contamination also occurs by depositions from the ambient air, gases, and liquids. Contamination by metals frequently results due to wear debris from moving metal parts, but also due to sputtering of metal parts in the processing chambers in plasma processes. Because metal atoms during incorporation in the silicon lattice usually produce deep-lying defect levels, their indiffusion in high temperature processes leads to increased recombination of charge carriers and a reduced minority carrier lifetime; furthermore, they act as a source for oxidation-induced stacking faults. The detection of metal contamination generally requires a high analytical expenditure.

Effective cleaning methods and/or drying methods must therefore eliminate the aforementioned contaminations between process steps or reduce it to a degree which is not critical for the functionality of the component.

In addition to mechanical cleaning methods, primarily dry chemical and wet chemical cleaning methods are known.

Whereas some compounds can be removed from the disk surface by simple rinsing in ultrapure water or deionized water, most contaminants by far, however, first require being converted to a soluble state. Acidic or basic solutions, oxidizing agents, and complexing agents are used for this purpose.

In practice, the cleaning and/or drying steps largely proceed automatically in centrifugal spray systems.

Centrifuges, in which the individual steps of the manufacturing process take place, are typically used in processes of this type. The centrifuges thereby use a drum, in which the wafers are kept during the process step. The drum in turn is disposed rotatable in a chamber in which nozzles are disposed that spray the wafers with liquids or gases. During the centrifugation process, the drum turns at high speed to provide, on the one hand, good distribution of the liquids on the wafers and, on the other, to provide for the removal of the liquids from the wafer surface by centrifugal force during the drying process.

Because in the manufacture of semiconductor elements, it is a matter of many defect-free runs within a short time, care must be taken in addition that the cleaning processes occur within a reasonable time.

A disadvantage of known cleaning and drying devices is that they typically include steel alloys. Because liquids, for example, deionized water, are used in cleaning and drying processes, which can dissolve atoms out of the steel alloys, there is the risk that foreign atoms in particular, such as, e.g., vanadium, tantalum, tungsten, or gold, but especially iron, chromium, nickel, oxygen, and carbon that are dissolved, come into contact with the wafer, and enter into the silicon lattice structure in the subsequent temperature processes. Iron atoms in particular adhere especially readily to the surfaces of wafers, whereby defect recombinations in the silicon crystal lattice due to crystal defects can then occur after the temperature processes. However, low contamination by foreign atoms is important for a high charge carrier lifetime and thereby for the quality of the wafers. This produces high requirements for the purity of the starting materials and all wet and high temperature processes, in which foreign atoms can be introduced especially rapidly.

In another conventional method for cleaning and drying of wafers, media such as isopropanol or alcohol/water mixtures are employed with use of the Marangoni effect, whereby very good results are achieved; nevertheless, the equipment for this process is far more expensive than for conventional methods.

### SUMMARY OF THE INVENTION

It is therefore an object of the present invention to minimize the number of particles in the cleaning process and to avoid contamination with metal ions while avoiding the aforementioned disadvantages.

Accordingly, an embodiment of the invention provides that a coating of a fluoropolymer is provided on all wafer processing device parts coming in contact with liquids in a wafer processing device, which comprises a processing chamber and within the processing chamber an arrangement of inlet openings and a rotatable holding device for wafers, whereby the wafers are disposed in wafer carriers and are fixed by these in the rotatable holding device. Because even the deionized water, which is used for cleaning, still contains harmful particles, there is the basic risk that these particles continue to adhere to the surface of the processing chamber and contaminate the wafers in the next cleaning procedure. In contrast to a surface made of steel or stainless steel, the surface of the fluoropolymer is hydrophobic. Therefore, no water, which perhaps could contain particles, continues to adhere to the surface.

Optical and electronic tests by the applicant have shown that the number of particles on the wafers after cleaning in a device according to the invention declines into a range below 2 to 5 particles per wafer, whereas before use of the device the particle count was between 10 and 25.

A coating in which polytetrafluoroethylene (PTFE) is provided as the fluoropolymer, proved to be especially advantageous here. It has a very low surface tension, so that no particles and no cleaning fluid can continue to adhere to the surface. Furthermore, a coating of PTFE offers the advantage that, in contrast to other fluoropolymers, it can be applied very thin. Therefore, only minor changes in mass occur in the machines, also in retrofitting. This is of great importance in centrifugal wafer processing devices, so that imbalances do not occur during the rotation.

Another embodiment of the invention provides that the fluoropolymer can be a perfluoroalkoxy copolymer (PFA).

According to an embodiment of the invention, a hard layer, that can be made of silicon carbide (SiC, S—SiC, or Si—SiC), is provided under the fluoropolymer coating. It is of particular advantage, furthermore, if the hard layer has a rough surface, like a ceramic surface which has peaks and valleys. According to an embodiment of the invention, the fluoropolymer coating is applied thin with a layer thickness in a range from 40 to 100 μm.

Because wafer processing devices are typically heated from outside by, for example, heating mats or the like for individual process steps, the advantage of a thin coating is that not too much heat energy is lost due to the insulating properties of the coating.

During application of the fluoropolymer layer to the rough hard layer, the thickness of the fluoropolymer layer on the peaks of the hard layer surface can be within the range of a few micrometers, whereas a layer with the aforementioned layer thickness of 40 to 100 μm collects in the valleys. During mechanical stress of the surface, the fluoropolymer layer thereby also remains in the valleys of the hard layer, even if the peaks should be damaged. The properties of the surface are retained overall as a result.

Furthermore, the invention provides a method for processing a wafer, in which initially one or more wafers are placed in a rotatable holding device of a processing chamber, whereby the holding device is provided with a fluoropolymer coating. After the wafers are fixed and the processing chamber is closed, the liquid is applied to the surface of the wafers via inlet openings disposed in the processing chamber. After the cleaning and rinsing process, the wafers are dried by rotating the holding device with use of centrifugal force.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a longitudinal section through a wafer processing device.

FIG. 2 shows a cross section through a wafer processing device.

FIG. 3 shows measurement results for the number of particles per wafer before and after the use of the device.

### DETAILED DESCRIPTION

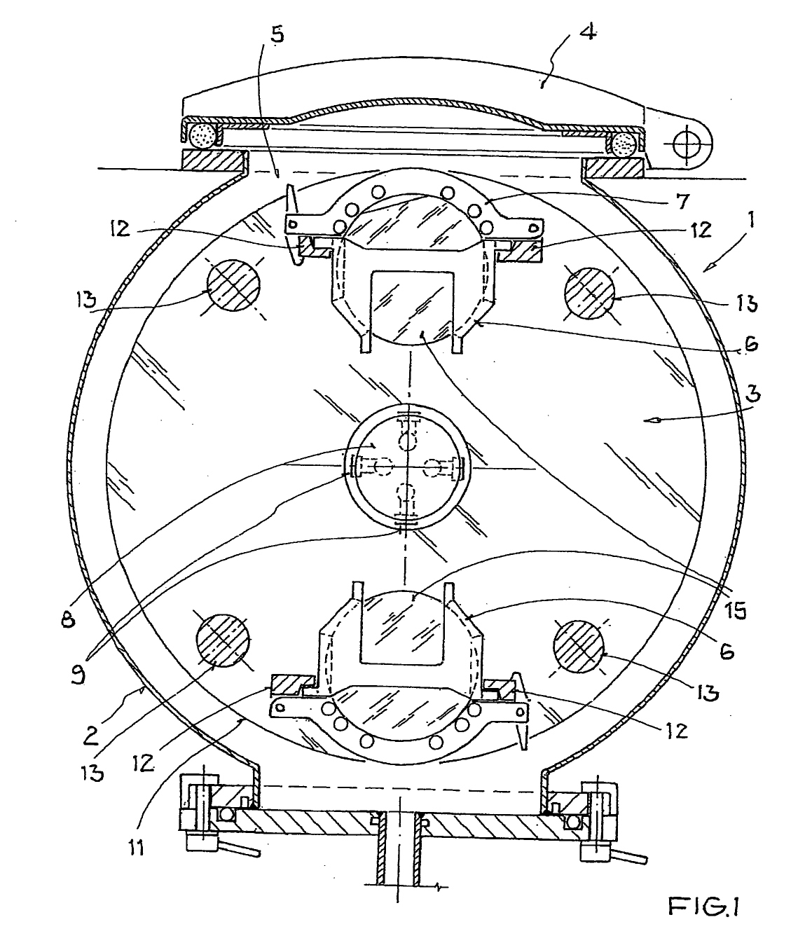

FIG. 1 shows a longitudinal section through a wafer processing device 1. This device has a processing chamber 3, which is closed off by a cylindrical housing 2 and in which a rotating holding device 11 for at least one wafer carrier 6 is disposed. During the cleaning process, holding device 11 is set in motion by a rotary drive 10, which penetrates housing 2. In processing chamber 3, in addition, a nozzle assembly 8 is disposed, which has a plurality of inlet openings 9, which introduce the specific cleaning liquid or a gas into the processing chamber 3.

Holding device 11 contains two support bars 12 each, in which wafer carriers 6 can be suspended. So that wafers 15 are also fixed during the rotary motion, they are held down by an enclosure 7, which is attached by hinges to support bars 12.

Holding device 11 is provided with rotary bearings 14 on both sides of housing 2. To reinforce holding device 11, a total of four rods 13 are disposed each on both sides of wafer carrier 6.

In the present embodiment, nozzle assembly 8 is disposed axially movable in the middle of housing 2. Other embodiments are also conceivable, however, in which nozzle assembly 8 is rigidly fixed on the bottom of housing 2.

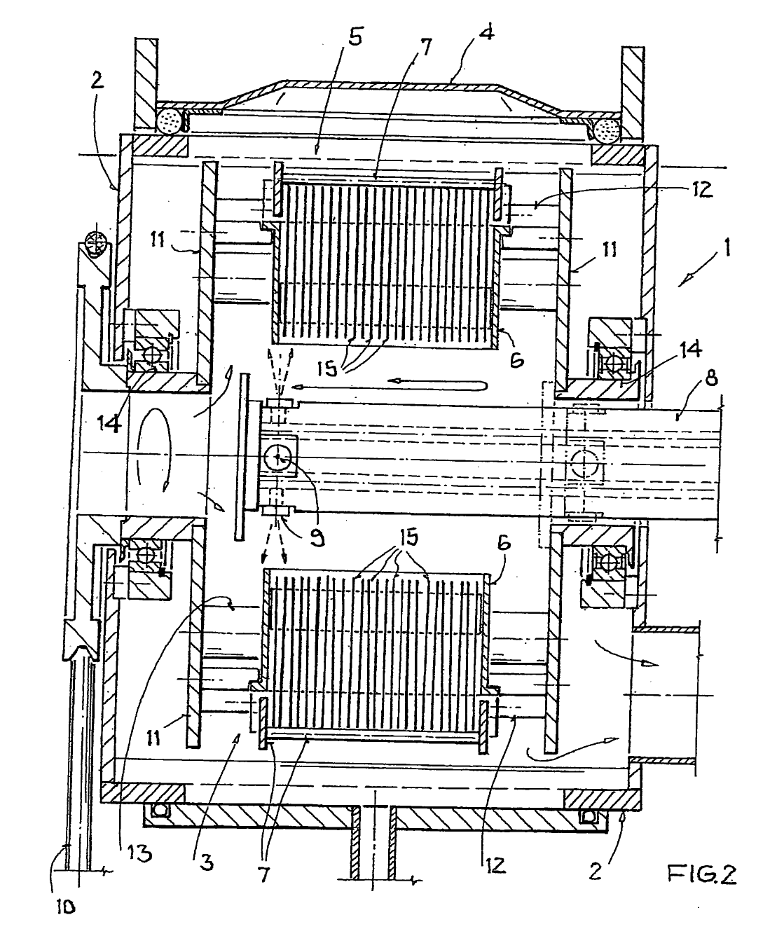

FIG. 2 shows a cross section through wafer processing device 1. Lid 4 is fixed by hinges to housing 2 and enables the loading and unloading of processing chamber 3. Cleaning fluids and cleaning gases are distributed through inlet openings 9 of nozzle assembly 8 in processing chamber 3.

In addition to housing 2 and its sealing lid 4, both holding device 11 and its individual parts, such as support bars 12 and rods 13, as well as rotary bearings 14, are typically made of steel or stainless steel. During the cleaning process, the cleaning fluid or cleaning gas flows around all of these structural parts lying within. The fluoropolymer coating on the individual parts of wafer processing device 1 provides that no metal ions could dissolve, which can cause the aforementioned damage to wafers 15 and that particles dissolved from wafers 15 during cleaning are not deposited in wafer processing device 1.

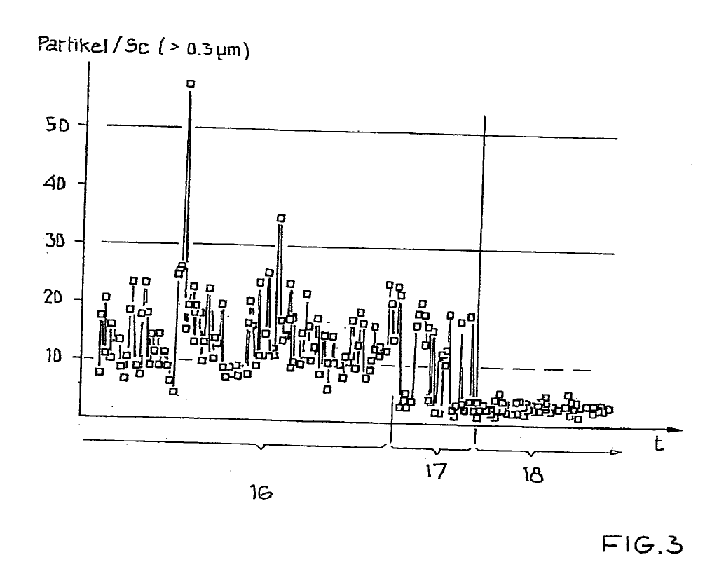

In the diagram of FIG. 3, the number of particles, which are larger than 0.3 μm and which can still be measured on the surface of a wafer after the cleaning process, is plotted versus a time axis 16, 17, 18. The first region 16 indicates the particle count after the cleaning and drying processes in conventional wafer processing devices according to the related art. In the second region 17, measurements were made after the use of conventional wafer processing devices and the testing of the wafer processing device of the invention. Region 18 finally provides the particle count after the use of the device of the invention. Here, each measured value corresponds to the number of measured particles on the wafer. Whereas the number of particles before use of the invention varies between 5 and 25, the particle count after use of the device according to the invention is within a range between 2 and 5 particles per wafer.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A wafer processing device comprising:
a processing chamber substantially surrounded by a housing;
an arrangement of inlet openings within the processing chamber, the arrangement being provided to dispense a liquid;
a rotatable holding device for wafers provided within the processing chamber, the wafers being disposed in a wafer carrier, which is fixedly attached to the holding device,
wherein a fluoropolymer coating is provided on substantially all parts of the wafer processing device that contacts the liquid.

2. The wafer processing device according to claim 1, wherein a hard layer is provided under the fluoropolymer coating.

3. The wafer processing device according to claim 2, wherein the hard layer is provided with a rough surface.

4. The wafer processing device according to claim 1, wherein the fluoropolymer is polytetrafluorethylene (PTFE).

5. The wafer processing device according to claim 1, wherein the fluoropolymer is a perfluoroalkoxy copolymer (PFA).

6. The wafer processing device according to claim 1, wherein the fluoropolymer has a layer thickness of 40 to 100 μm.

7. A method for processing a wafer, the method comprising;
inserting at least one wafer carrier having at least one wafer into a rotatable holding device of a processing chamber, the holding device being provided with a fluoropolymer coating;
applying a liquid to a surface of the wafer via inlet openings that are disposed in the processing chamber;
drying the wafers by rotating the holding device through centrifugal force.

8. The wafer processing device according to claim 2, wherein the hard layer is silicon carbide (SiC).
